(19) United States
(12) Patent Application Publication
(10) Pub. No.: US 2004/0150975 A1
(43) Pub. Date: Aug. 5, 2004

(54) Image sensor having a frame layer formed with a venthole

(76) Inventors: Jackson Hsieh, Hsinchu Hsien (TW); Jichen Wu, Hsinchu Hsien (TW); Bruce Chen, Hsinchu Hsien (TW); Sam Hiew, Hsinchu Hsien (TW); Jian-Hsian Lu, Hsinchu Hsien (TW); Wen-Yang Chang, Hsinchu Hsien (TW)

Correspondence Address: PRO-TECHTOR INTERNATIONAL, 20775 Norada Court, Saratoga, CA, 95070-3018, US

(21) Appl. No.: 10/356,757

(22) Filed: Jan. 30, 2003

(51) Int. Cl. H05K 7/02; H05K 7/04

(52) U.S. Cl. 361/807

(57) ABSTRACT

An improved structure of an image sensor includes a substrate, a frame layer on the substrate to form a chamber together with the substrate, a photosensitive chip arranged on the substrate and within the chamber, a plurality of wires, a transparent layer placed on the frame layer, and a filling medium. The frame layer is formed with at least one venthole communicating with the chamber. The wires electrically connect the chip to the substrate. The filling medium is filled into the venthole of the frame layer to seal the chamber. Accordingly, the air pressure within the chamber generated when the transparent layer is fixed to the frame layer may be released through the venthole, and the transparent layer may be firmly fixed to the frame layer.

### BACKGROUND OF THE INVENTION

1. Field of the Invention

The invention relates to an improved structure of an image sensor, and more particularly to an image sensor having a transparent layer that may be firmly adhered to a frame layer thereof, and also to an image sensor that may be manufactured conveniently and with high production yield.

2. Description of the Related Art

Referring to FIG. 1, a conventional image sensor includes a substrate 10, a frame layer 18, a photosensitive chip 26, a plurality of wires 28, and a transparent layer 34. The substrate 10 has a first surface 12 on which a plurality of signal input terminals 15 are formed, and a second surface 14 on which a plurality of signal output terminals 16 are formed. The frame layer 18 has an upper surface 20 and a lower surface 22 adhered to first surface 12 of the substrate 10 to form a cavity 24 together with the substrate 10. The photosensitive chip 26 is arranged within the cavity 24 and is mounted to the first surface 12 of the substrate 10. Each wire 28 has a first terminal 30 and a second terminal 32. The first terminals 30 are electrically connected to the photosensitive chip 26, and the second terminals 32 are electrically connected to the signal input terminals 15 of the substrate 10. The transparent layer 34 is adhered to the upper surface 20 of the frame layer 18.

When the transparent layer 34 is adhered to the frame layer 18, the air within the cavity 24 may apply a force against the transparent layer 34 to push the transparent layer 34 away from the frame layer 18 because the cavity 24 is a closed chamber. Thus, the adhesion force of the transparent layer 34 is reduced so that the transparent layer 34 tends to be peeled off or the cavity 24 tends to be non-airtight. In this case, the outside air or impurities may enter the cavity 24 to influence the image sensor quality.

### SUMMARY OF THE INVENTION

An object of the invention is to provide an improved structure of an image sensor that can be manufactured conveniently and has a lower manufacturing costs.

Another object of the invention is to provide an improved structure of an image sensor having a transparent layer that is firmly adhered to the frame layer so that the production yield may be increased.

To achieve the above-mentioned objects, the improved structure of an image sensor includes a substrate, a frame layer, a photosensitive chip, a plurality of wires, a transparent layer, and a filling medium.

The substrate has an upper surface and a lower surface. The frame layer has a top face and a bottom face adhered to the upper surface of the substrate. A chamber is defined between the substrate and the frame layer. At least one venthole communicating with the chamber is formed on the frame layer. The photosensitive chip has a photosensitive region and a plurality of bonding pads formed at a periphery of the photosensitive region. The photosensitive chip is arranged on the upper surface of the substrate and within the chamber. Each wire has a first terminal and second terminal. The first terminals are electrically connected to the bonding pads of the photosensitive chip, respectively, and the second terminals are electrically connected to the substrate. The transparent layer is adhered to the top face of the frame layer. The filling medium is filled into the at least one venthole to seal the chamber.

Accordingly, the air pressure within the chamber generated when the transparent layer is fixed to the frame layer may be released throng the venthole, and the transparent layer may be firmly fixed to the frame layer.

### BRIEF DESCRIPTION OF THE DRAWINGS

FIG. 1 is a cross-sectional view showing a conventional package structure of an image sensor.

FIG. 2 is a cross-sectional view showing an image sensor of the invention with an unclosed venthole.

FIG. 3 is a cross-sectional view showing the image sensor of the invention with a closed venthole.

FIG. 4 is a pictorial view showing another embodiment of the invention.

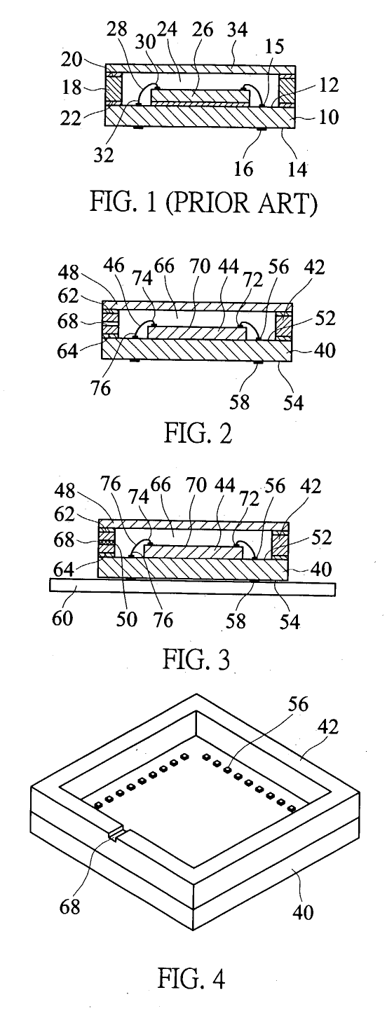

### DETAILED DESCRIPTION OF THE INVENTION

Referring to FIGS. 2 and 3, an image sensor according to an embodiment of the invention includes a substrate 40, a frame layer 42, a photosensitive chip 44, a plurality of wires 46, a transparent layer 48 and a filling medium 50.

The substrate 40 has an upper surface 52 on which a plurality of signal input terminals 56 are formed, and a lower surface 54 on which a plurality of signal output terminals 58 are formed. The signal output terminals 58 are electrically connected to a printed circuit board 60 to transfer signals to the printed circuit board 60.

The frame layer 42 has a top face 62 and a bottom face 64 adhered to the upper surface 52 of the substrate 40. A chamber 66 is defined between the substrate 40 and the frame layer 42. At least one venthole 68 is formed on a side face of the frame layer 42.

The photosensitive chip 44 has a photosensitive region 70 and a plurality of bonding pads 72 formed at a periphery of the photosensitive region 70. The chip 44 is arranged on the upper surface 52 of the substrate 40 and within the chamber 66.

Each of the wires 46 has a first terminal 74 and a second terminal 76. The first terminals 74 are electrically connected to the bonding pads 72 of the photosensitive chip 44, and the second terminals 76 are electrically connected to the signal input terminals 56 of the substrate 40, respectively. Thus, signals from the photosensitive chip 44 may be transferred to the substrate 40 via the wires 46.

The transparent layer 48 is a piece of transparent glass, mounted to the top face 62 of the frame layer 42 to cover the photosensitive chip 44. At this time, the air is vented out through the venthole 68 and the air pressure within the chamber 66 is released through the venthole 68. Therefore, the process for placing the transparent layer 48 on the frame layer 42 is more convenient, and the transparent layer 48 may be fixed to the frame layer 42 more firmly.

The filling medium 50 is a glue material filled into the venthole 68 by heat-melting or glue dispensing so as to seal the chamber 66 after the transparent layer 48 is adhered to the frame layer 42.

Referring to FIG. 4, the venthole 68 is formed on the top face 62 of the frame layer 42 and is integrally formed upon the formation of the frame layer 42. Thus, the venthole 68 may be manufactured more conveniently. Similarly, after the transparent layer 48 is adhered to the frame layer 42, the glue material is filled into the venthole 68 to seal the chamber 66 by heat-melting or glue dispensing.

The image sensor of the invention has the following advantages.

1. The venthole 68 is formed on a side face or a top face of the frame layer 42, the air pressure within the chamber 66 may be released through the venthole 68 when the transparent layer 48 is adhered to the top face 62 of the frame layer 42. So, the process for adhering the transparent layer 48 to the frame layer 42 may be performed more conveniently, and the transparent layer 48 may be adhered to the frame layer 42 more firmly.

2. Since the venthole 68 and the frame layer 42 are integrally formed, the manufacturing processes are more easily.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. An image sensor to be electrically connected to a printed circuit board, the image sensor comprising:
a substrate having an upper surface and a lower surface;
a frame layer having a top face and a bottom face adhered to the upper surface of the substrate, a chamber being defined between the substrate and the frame layer, and at least one venthole communicating with the chamber being formed on the frame layer;
a photosensitive chip having a photosensitive region and a plurality of bonding pads formed at a periphery of the photosensitive region, the photosensitive chip being arranged on the upper surface of the substrate and within the chamber;
plural wires, each of which having a first terminal and second terminal, the first terminals being electrically connected to the bonding pads of the photosensitive chip, respectively, and the second terminals being electrically connected to the substrate;
a transparent layer adhered to the top face of the frame layer; and
a filling medium filled into the at least one venthole to seal the chamber.

2. The image sensor according to claim 1, further comprising a plurality of signal input terminals formed on the upper surface of the substrate, wherein the second terminals of the wires are electrically connected to the signal input terminals, respectively.

3. The image sensor according to claim 1, further comprising a plurality of signal output terminals formed on the lower surface of the substrate to electrically connect the substrate to the printed circuit board.

4. The image sensor according to claim 1, wherein the at least one venthole is formed on a side face of the frame layer.

5. The image sensor according to claim 1, wherein the at least one venthole is integrally formed on the top face of the frame layer upon formation of the frame layer.

6. The image sensor according to claim 1, wherein the transparent layer is a piece of transparent glass.

7. The image sensor according to claim 1, wherein the filling medium is a glue material filled into the at least one venthole by heat-melting or glue dispensing.
